(19) United States
(12) Patent Application Publication
(10) Pub. No.: US 2025/0142964 A1
(43) Pub. Date: May 1, 2025

(54) DISPLAY PANEL AND ELECTRONIC DEVICE

(71) Applicant: Yungu (Gu’an) Technology Co., Ltd., Langfang (CN)

(72) Inventors: Linhua GAO, Langfang (CN); Panpan QIAO, Langfang (CN); Sheng GUO, Langfang (CN); Miaomiao TIAN, Langfang (CN); Zhili MA, Langfang (CN)

(73) Assignee: Yungu (Gu’an) Technology Co., Ltd., Langfang (CN)

(21) Appl. No.: 18/885,837

(22) Filed: Sep. 16, 2024

(30) Foreign Application Priority Data
Oct. 30, 2023 (CN) 202311425668.6

(51) Int. Cl. H01L 27/12

(52) U.S. Cl. CPC H10D 86/60; H10D 86/443

(57) ABSTRACT

A display panel and an electronic device. The display panel has a display area and a non-display area. The display panel includes a base, a first signal transmission layer, a second signal transmission layer, a first dam, and a second dam. The first signal transmission layer is disposed on the base. The second signal transmission layer is disposed on a surface of a side of the first signal transmission layer away from the base. A first orthographic projection is defined by an orthographic projection of the second dam on the base. A second orthographic projection is defined by an orthographic projection of a second end portion of the second signal transmission layer on the base. The first orthographic projection is located at a side of the second orthographic projection close to the display area.

### CROSS-REFERENCE TO RELATED APPLICATIONS

This application claims priority to Chinese Patent Application No. 202311425668.6, filed on Oct. 30, 2023 in the National Intellectual Property Administration of China, the contents of which are herein incorporated by reference in their entireties.

### TECHNICAL FIELD

The present disclosure relates to the field of display technologies, and in particular to a display panel and an electronic device.

### BACKGROUND

With the development of an electronic device, such as a cell phone display technology, people are having a higher expectation in a bezel, a display brightness, and a display performance of a display panel of the electronic device.

### SUMMARY

Some embodiments of the present disclosure provide a display panel and an electronic device, in order to address a conflict between narrowing a bezel and improving a display brightness and a display performance in an existing display panel.

In order to address the technical problem above, a technical solution adopted by some embodiments of the present disclosure provides a display panel. The display panel has a display area and a non-display area. The display panel includes a base, a first signal transmission layer, a second signal transmission layer, a first dam, and a second dam. The first signal transmission layer is disposed on the base. The second signal transmission layer is disposed on a surface of a side of the first signal transmission layer away from the base. The first dam and the second dam are located at the non-display area and spaced apart from one another along an extending direction of the second signal transmission layer on a surface of a side of the second signal transmission layer away from the base. The second dam is located at a side of the first dam away from the display area. A first orthographic projection is defined by an orthographic projection of the second dam on the base. A second orthographic projection is defined by an orthographic projection of a second end portion of the second signal transmission layer on the base. The first orthographic projection is located at a side of the second orthographic projection close to the display area.

In order to address the technical problem above, a technical solution adopted by some embodiments of the present disclosure provides an electronic device. The electronic device includes the display panel mentioned above.

### BRIEF DESCRIPTION OF THE DRAWINGS

FIG. 1a is a schematic structural view of a display panel according to an embodiment of the present disclosure.

FIG. 1b is a schematic top view of the display panel illustrated in FIG. 1a according to an embodiment of the present disclosure.

FIG. 2 is a schematic structural view of a display panel according to another embodiment of the present disclosure.

FIG. 3a is a schematic structural view of a display panel according to still another embodiment of the present disclosure.

FIG. 3b is a schematic top view of the display panel illustrated in FIG. 3a according to still another embodiment of the present disclosure.

FIG. 4a is a schematic structural view of a display panel according to still another embodiment of the present disclosure.

FIG. 4b is a schematic top view of the display panel illustrated in FIG. 4a according to still another embodiment of the present disclosure.

FIG. 5 is a schematic structural view of an electronic device according to an embodiment of the present disclosure.

### DETAILED DESCRIPTION

The technical solutions according to the embodiments of the present disclosure are clearly and thoroughly described below in conjunction with the drawings in the embodiments of the present disclosure. Obviously, the embodiments described are merely some embodiments, rather than all embodiments, of the present disclosure. Based on the embodiments of the present disclosure, any other embodiment obtained by a person of ordinary skills in the art without creative work fall within the scope of protection of the present disclosure.

The terms “first”, “second”, and “third” in the present disclosure are used for descriptive purposes only and may not be understood as indicating or implying a relative importance or implicitly specifying the number of technical features indicated. Thus, a feature defined with the terms “first”, “second”, and “third” may, either explicitly or implicitly, indicate that at least one such feature is provided. In the description of the present disclosure, “plurality” means at least two, e.g., two, three, and etc., unless otherwise explicitly and specifically indicated. All directional indications (e.g., top, bottom, left, right, front, and back . . . ) in the embodiments of the present disclosure are only used to explain a relative positional relationship, a movement, and etc. between components with respect to a particular position (as illustrated in the drawings), and the directional indications may be changed correspondingly when the position changes. In addition, the terms “including”, “having”, and any variation thereof are intended to indicate a non-exclusive inclusion. For example, a process, a method, a system, a product or a device that includes a series of steps or units may not be limited to merely include the aforementioned steps or units, but optionally may further include a step or unit that is not mentioned, or any other step or unit that is inherent to the process, the method, the product or the device.

A reference to an “embodiment” in the specification of the present disclosure indicates that a particular feature, structure, or characteristic described in conjunction with the embodiment may be provided in at least one embodiment of the present disclosure. The “embodiment” mentioned across the entire specification neither necessarily refers to the same embodiment, nor necessarily refers to a separate or alternate embodiment that is mutually exclusive with other embodiments. It should be understood by the person of ordinary skills in the art, both explicitly and implicitly, that any embodiment described herein may be combined with other embodiments.

In conjunction with the drawings and the embodiments, the present disclosure is described in detail in the following.

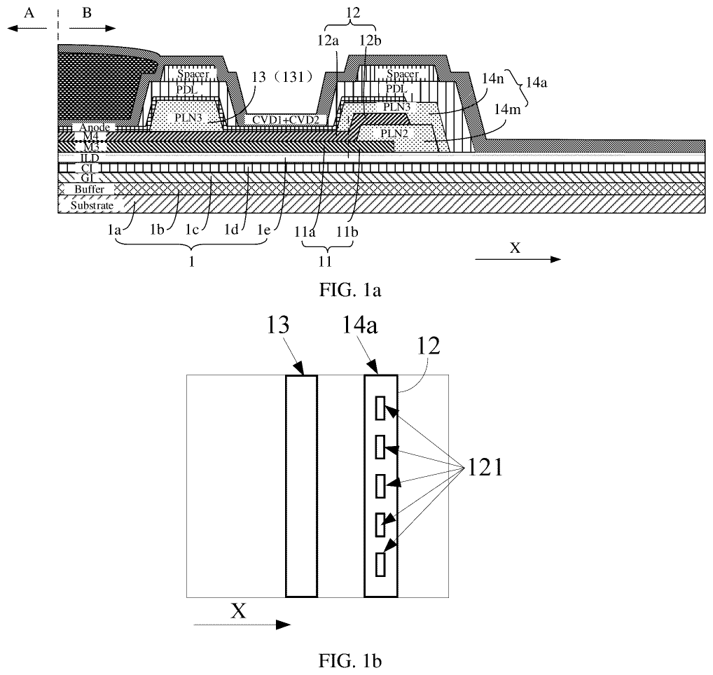

As illustrated in FIG. 1a, FIG. 1a is a schematic structural view of a display panel 10a according to an embodiment of the present disclosure. The display panel 10a may be provided by some embodiments of the present disclosure. The display panel 10a has a display area A and a non-display area B. The display area A is configured to display an image in operation. The non-display area B does not display an image.

As illustrated in FIG. 1a, the display panel 10a includes a base 1, a first signal transmission layer 11, a second transmission layer 12, a first dam or dam 13, and a second dam 14a.

The base 1 includes a substrate 1a, a buffer layer 1b, a thin film transistor array, a gate insulating layer (i.e., GI) 1c, an insulating layer (i.e., CI) 1d, and a dielectric layer 1e. The insulating layer 1d is configured to form a capacitor. The substrate 1a may be flexible, extendable, foldable, bendable, or pliable, which enables the display panel 10a to be flexible, extendable, foldable, bendable, or pliable. The substrate 1a may be formed by any suitable flexible insulating material, such as a polyimide (PI), a polycarbonate (P), a polyethersulfone (PES), a polyethylene terephthalate (PET), a polyethylene naphthalene dicarboxylate (PEN), a polyarylate (PR), fiberglass reinforced plastics (FRP), or other polymeric materials. The substrate 1a may be transparent, translucent, or opaque.

The buffer layer 1b, the GI layer 1c, the CI layer 1d, and the dielectric layer 1e are stacked on a surface of a side of the substrate 1a in sequence. In some embodiments, the thin film transistor array includes a plurality of thin film transistors. Each thin film transistor includes a semiconductor active layer, a gate electrode, a source electrode, and a drain electrode. The semiconductor active layer includes a source area and a drain area. The source area and the drain area are formed through doping an N-type impurity ion or a P-type impurity ion. A channel area is defined between the source area and the drain area. The channel area is an area where no impurity is doped.

Each of the first signal transmission layer 11 and the second signal transmission layer 12 is a metal layer and is configured to transmit a signal. The first signal transmission layer 11 is disposed on the base 1. The second transmission layer 12 is disposed on a side of the first signal transmission layer 11 away from the base 1. In some embodiments, the first signal transmission layer 11 and the second signal transmission layer 12 are stacked on a side of the dielectric layer 1e away from the substrate 1a. The first signal transmission layer 11 and the second signal transmission layer 12 are configured to transmit a signal, such as an ELVSS signal, an ELVDD signal, a DATA signal, etc., to a pixel circuit. In the present embodiment, the first signal transmission layer 11 and the second signal transmission layer 12 are configured to transmit the ELVSS signal.

In some embodiments, the first signal transmission layer 11 includes a first body portion 11a and a first end portion 11b. Along a direction of the non-display area B away from the display area A, the first end portion 11b is connected to a side of the first body portion 11a away from the display area A. The second signal transmission layer 12 includes a second body portion 12a and a second end portion 12b. Along the direction of the non-display area B away from the display area A, the second end portion 12b is connected to a side of the second body portion 12a away from the display area A.

The first dam 13 and the second dam 14a are spaced apart on the non-display area B of the display panel 10a and are configured to avoid an organic adhesive for encapsulation at the display area A from overflowing. The first dam 13 is disposed on a surface of a side of the second body portion 12a away from the base 1 and is located at a side of the second dam 14a close to the display area A. A material of each of the first dam 13 and the second dam 14a may include an organic film layer, such as an acrylic, a PI, a benzocyclobutene (BCB), and so on. Along a first direction X, a first width is defined by a distance between the second dam 14a and the display area A of the display panel 10a.

In some embodiments, as illustrated in FIG. 1a, the second dam 14a includes a first organic layer (i.e., PLN2) 14m and a second organic layer (i.e., PLN3) 14n. The first organic layer 14m is disposed on the base 1 and covers the first end portion 11b of the first signal transmission layer 11. The second end portion 12b of the second signal transmission layer 12 is disposed on a surface of a side of the first organic layer 14m away from the first signal transmission layer 11. The second organic layer 14n is disposed on a surface of a side of the second end portion 12b away from the first organic layer 14m and covers a surface of side of the first organic layer 14m away from the display area A, thereby covering the second end portion 12b. In this way, the second dam 14a is configured to not only protect the first end portion 11b of the first signal transmission layer 11 and the second end portion 12b of the second signal transmission layer 12, but also avoid the first signal transmission layer 11 and the second signal transmission layer 12 from a corrosion or a short circuit due to contact with other conductive materials.

The first organic layer 14m is not only disposed between the second end portion 12b and the first end portion 11b but also between the second end portion 12b and the base 1. Since a material of the first organic layer 14m is organic, water vapor may be generated by the first organic layer 14m during a high-temperature manufacturing process, which further leads to a bubble in the second signal transmission layer 12. Therefore, as illustrated in FIG. 1b, a schematic top view of the display panel illustrated in FIG. 1a according to an embodiment of the present disclosure, a surface the second signal transmission layer 12 away from the base 1 is coated with an adhesive to form a mask thereon. The mask is configured to etch a part of the second signal transmission layer 12 that corresponds to the first organic layer 14m to form a water vapor release hole 121. The water vapor release hole 121 is configured to release the water vapor generated by the first organic layer 14m during the manufacturing process.

However, as illustrated in FIG. 1a, since the first end portion 11b of the first signal transmission layer 11 and the second end portion 12b of the second signal transmission layer 12 are located in the second dam 14a, in order to realize a narrow bezel of the display panel 10a, the first width defined between the second dam 14a and the display area A along the first direction X is reduced. That is to say, a size of each of the first signal transmission layer 11 and the second signal transmission layer 12 is reduced, i.e., a width of each of the first signal transmission layer 11 and the second signal transmission layer 12 along the first direction X is decreased. Thus, a high-brightness display of the display panel 10a may not be realized. In order to realize the high-brightness display of the display panel 10a, the width of at least one of the first signal transmission layer 11 and the second signal transmission layer 12 along the first direction X needs to be increased, which reduces a resistance of the at least one of the first signal transmission layer 11 and the second signal transmission layer 12, thereby further reducing a voltage drop and an energy consumption and realizing the high-brightness display of the display panel 10a. That is to say, in the present embodiment, a width of the bezel area is increased correspondingly in order to realize the high-brightness display of the display panel 10a. Therefore, the technical solution described above may result in a conflict between realizing a narrow bezel of the display panel 10a and improving the display brightness and the display performance.

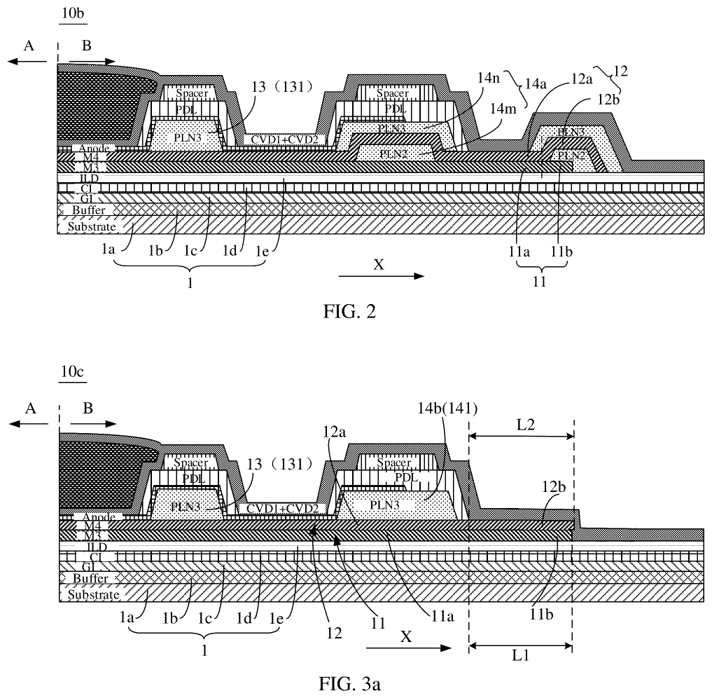

Therefore, a display panel 10b is further provided by another embodiment of the present disclosure. FIG. 2 is a schematic structural view of a display panel according to another embodiment of the present disclosure. As illustrated in FIG. 2, in contrast to the display panel 10a mentioned above, the display panel 10b increases a width of an ELVSS wiring through extending the ELVSS wiring. That is, the second signal transmission layer 12 is disposed along a surface of a side of the first organic layer 14m away from the base 1, extends to a side of the second dam 14a away from the first dam 13 and further extends along a direction away from the second dam 14a, which increases a width of the second body portion 12a along the first direction X, thereby realizing a high-brightness display of the display panel 10b. In addition, the extended metal wiring laps a vapor chemical deposition layer (i.e., CVD1+CVD2), which allows the extended metal wiring to have a relatively small effect on an overall encapsulation width of the display panel 10b and the narrow bezel of the display panel 10b, thereby realizing both the narrow bezel and the high-brightness display of the display panel 10b.

As illustrated in FIG. 2, at a location where the second signal transmission layer 12 is disposed on a surface of a side of the first organic layer 14m away from the base 1, the first organic layer 14m is disposed not only between the first signal transmission layer 11 and the second signal transmission layer 12 but also between the second signal transmission layer 12 and the base 1. Based on a long-term research of the inventor of the present disclosure, during the process of forming the water vapor release hole 121 on the surface of a side of the second signal transmission layer 12 away from the base 1 through a yellow-light coating, due to a leveling property of a photoresist, along a layering direction of the display panel 10b, a relatively small amount of the photoresist remains on a surface of a side of the second signal transmission layer 12 away from the first organic layer 14m, which forms a relatively thin photoresist layer. Thus, during an etching process of the second signal transmission layer 12, an over-etching phenomenon occurs at a patterned portion of the second signal transmission layer 12 that corresponds to the first organic layer 14m. In case of a severe over-etching phenomenon occurring, a portion of the second signal transmission layer 12 that corresponds to the second dam 14a may be completely fractured, resulting in a width of the second signal transmission layer 12 along the first direction X being reduced and the resistance being increased. In this case, in order to realize the high-brightness display, a corresponding current may be increased greatly, thereby leading to an excessively high temperature of the display panel 10b. Besides, the over-etching phenomenon may further result in an abnormal shape and a less reliable encapsulation of the second signal transmission layer 12, thereby leading to a problem, such as a black spot and a bright line, of the display panel under a high-temperature and high-humidity environment and further leading to a failure in the electronic device.

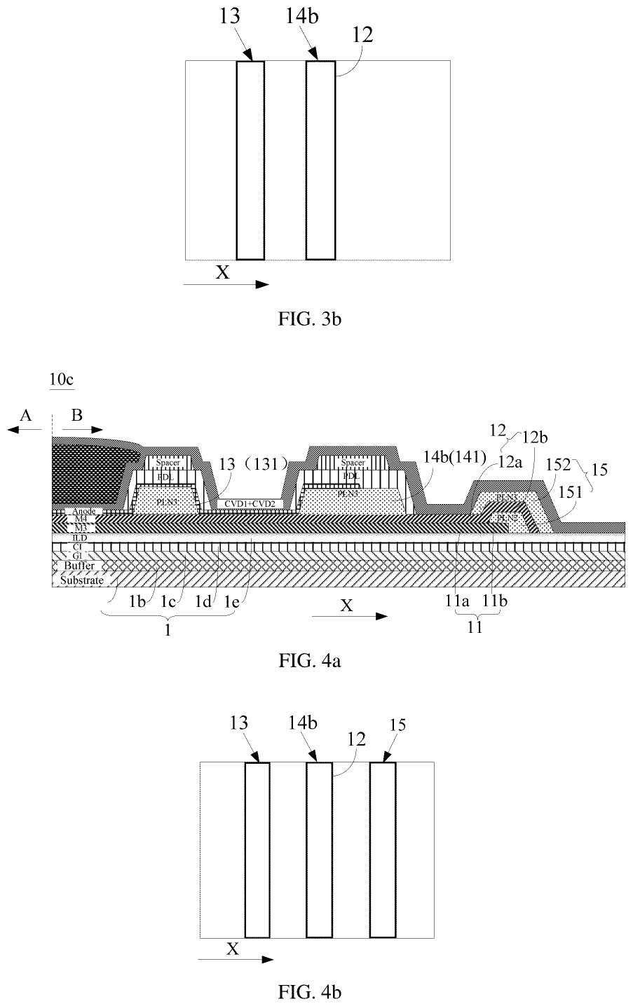

Therefore, as illustrated in FIG. 3a and FIG. 3b, a technical solution is provided by some embodiments of the present disclosure. FIG. 3a is a schematic structural view of a display panel according to still another embodiment of the present disclosure. FIG. 3b is a schematic top view of the display panel illustrated in FIG. 3a according to still another embodiment of the present disclosure. A display panel 10c is provided by still another embodiment of the present disclosure. The display panel 10c includes the base 1, the first signal transmission layer 11, the second signal transmission layer 12, the first dam 13, and a second dam 14b. In contrast to the display panel 10b as illustrated in FIG. 2, the second signal transmission layer 12 of the display panel 10c is disposed or stacked on and in contact with the first signal transmission layer 11. In addition, the first dam 13 and the second dam 14b are spaced apart on the surface of a side of the second signal transmission layer 12 away from the base 1 along an extending direction of the second signal transmission layer 12. A first orthographic projection is defined by an orthographic projection of the second dam 14b on the base 1. A second orthographic projection is defined by an orthographic projection of the second end portion 12b of the second signal transmission layer 12 on the base 1. The first orthographic projection is located at a side of the second orthographic projection close to the display area A. In other words, the second signal transmission layer 12 extends to a side of the second dam 14b close to an edge of the base 1 along the first direction X. That is, compared to the second signal transmission layer 12 illustrated in FIG. 1a, the second signal transmission layer 12 of the display panel 10c extends along the first direction X away from the display area A.

Furthermore, in some embodiments, a third orthographic projection is defined by an orthographic projection of the first end portion 11b of the first signal transmission layer 11 on the base 1. The first orthographic projection is located at a side of the third orthographic projection close to the display area A. In other words, the first signal transmission layer 11 extends to a side of the second dam 14b close to an edge of the base 1 along the first direction X. That is, with respect to the first signal transmission layer 11 illustrated in FIG. 1a, the first signal transmission layer 11 of the display panel 10c further extends along the first direction X away from the display area A.

A distance between an end of the first signal transmission layer 11 away from the display area A (i.e., the first end portion 11b) and the orthographic projection of the second dam 14b on the base 1 along the first direction X is defined as a first size L1, and the first side L1 is substantially 30 μm-50 μm. In some embodiments, L1 may be 30 μm, 35 μm, 40 μm, 45 μm, or 50 μm. A distance between an end of the second signal transmission layer 12 away from the display area A (i.e., the second end portion 12b) and the orthographic projection of the second dam 14b on the base 1 along the first direction X is defined as a second size L2, and the second size L2 is substantially 30 μm-50 μm. In some embodiments, L2 may be 30 μm, 35 m, 40 μm, 45 μm, or 50 μm.

In some embodiments, an extending distance of the first signal transmission layer 11 of the display panel 10c illustrated in FIGS. 3a-3b with respect to the first signal transmission layer 11 illustrated in FIG. 1a is

$$La = L 1 + \frac{1}{2} W 2.$$

W2 is a width of the second dam 14b along the first direction X. An extending distance of the second signal transmission layer 12 of the display panel 10c illustrated in FIGS. 3a-3b with respect to the second signal transmission layer 12 illustrated in FIG. 1a is

$$Lb = L 2 + \frac{1}{2} W 2.$$

That is to say, when each of the L1 and the L2 is substantially 30 μm, since the display panel 10c has a double-layer wiring, an ELVSS wiring of the display panel 10c extends at least L1+L2=60 μm compared to the structure illustrated in FIG. 1a along the first direction X.

It is to be noted that, a width of each of the first dam 13 and the second dam 14b along the first direction X refers to a width of each of the first dam 13 and the second dam 14b along the first direction X at a middle point of each of the first dam 13 and the second dam 14b in a direction substantially perpendicular to the base 1.

As mentioned above, the first signal transmission layer 11 and the second signal transmission layer 12 are extended, the second signal transmission layer 12 is disposed or stacked on the first transmission layer 11, and the first dam 13 and the second dam 14b are disposed on a surface of a side of the second signal transmission layer 12 away from the base 1. That is to say, at positions where the first dam 13 and the second dam 14b are located, no other structural layer, e.g., the first organic layer 14m, is disposed between the first signal transmission layer 11 and the second signal transmission layer 12. In other words, in contrast to the display panel 10a and display panel 10b above, the first organic layer 14m below the second dam 14b is removed from the display panel 10c. In this way, in addition to narrowing the bezel and realizing the high-brightness display, the display panel 10c further ensures that no height difference exists between a part of the second signal transmission layer 12 that corresponds to each of the first dam 13 and the second dam 14b and the remaining part of the second signal transmission layer 12, thereby further avoiding the over-etching phenomenon occurring at a part of the second signal transmission layer 12 that corresponds to each of the first dam 13 and the second dam 14b due to a non-uniform thickness of the photoresist resulted from a leveling process of the photoresist during a coating process. Therefore, the display panel 10c avoids the over-etching phenomenon that results in a part of the second signal transmission layer 12 that corresponds to the second dam 14b to be completely fractured. The fracture may reduce the width of the second signal transmission layer 12 along the first direction X and increase the resistance. In this way, in case of the high-brightness display, the corresponding current may be increased greatly, thereby leading to an excessively high temperature of the display panel 10c. In some embodiments, the over-etching phenomenon may further result in an abnormal shape and a less reliable encapsulation of the second signal transmission layer 12, thereby leading to a problem, such as a black spot and a bright line, of the display panel under a high-temperature and high-humidity environment and further leading to a failure in the electronic device. Moreover, through removing the first organic layer 14m below the second dam 14b, the display panel 10c further enables the second signal transmission layer 12 to directly lap the first signal transmission layer 11 at a position where the second dam 14b is located, which increases an effective lap area between the first signal transmission layer 11 and the second signal transmission layer 12 and reduces the resistance.

In some embodiments, as illustrated in FIG. 3a, the second body portion 12a is disposed on a surface of a side of the first body portion 11a away from the base 1. An orthographic projection of each of the first dam 13 and the second dam 14b on the base 1 is located within an orthographic projection of each of the first body portion 11a and the second body portion 11b. That is, each of the first body portion 11a and the second body portion 11b extends to a side of the second dam 14b away from the first dam 13. Compared to the display panel 10a illustrated in FIG. 1a, the display panel 10c greatly increases the width of each of the first signal transmission layer 11 and the second signal transmission layer 12 along the first direction X, thereby improving the display brightness and the display performance.

In some embodiments, the first dam 13 includes a third blocking layer 131, and the second dam 14b includes a fourth blocking layer 141. The third blocking layer 131 and the fourth blocking layer 141 are disposed or stacked on a surface of a side of the second signal transmission layer 12 away from the base 1. That is, the third blocking layer 131 and the fourth blocking layer 141 are disposed on the same layer. In this way, the third blocking layer 131 and the fourth blocking layer 141 may be manufactured through the same process. In some embodiments, the first dam 13 and the second dam 14b may be manufactured through the same process, thereby simplifying the manufacturing process and improving the efficiency.

In some embodiments, along a layering direction of the display panel 10c, a first distance is defined by a distance between the base 1 and a surface of a side of the third blocking layer 131 away from the base 1. A second distance is defined by a distance between the base 1 and a surface of a side of the fourth blocking layer 141 away from the base 1. The first distance is substantially equal to the second distance. In addition, a thickness of the third blocking layer 131 is substantially equal to a thickness of the fourth blocking layer 141 along the layering direction of the display panel 10c. In this way, even though the first organic layer 14m of the second dam 14a is removed, the display panel 10c still ensures an overall height of the second dam 14b to be substantially equal to an overall height of the first dam 13. That is, the overall height of the second dam 14b is not affected, which further avoids a flatness of any other functional layer, such as a pixel defining layer (PDL) to be affected.

In some embodiments, as illustrated in FIG. 3b, a part of each of the first signal transmission layer 11 and the second signal transmission layer 12 that corresponds to each of the first dam 13 and the second dam 14b is a continuous film layer. The continuous film layer refers to a film layer without any hole or recess defined thereon, i.e., a complete film structure. That is to say, the water vapor release hole 121 is not defined on the part of the second signal transmission layer 12 that corresponds to the second dam 14b. In this way, the over-etching phenomenon occurred when the second signal transmission layer 12 is etched to form the water vapor release hole 121 may be avoided, thereby avoiding a part of the first signal transmission layer 11 that corresponds to the second dam 14b from being fractured to ensure a width of the first signal transmission layer 11 along the first direction X and reducing the voltage drop.

As illustrated in FIG. 4a and FIG. 4b, FIG. 4a is a schematic structural view of a display panel according to still another embodiment of the present disclosure. FIG. 4b is a schematic top view of the display panel illustrated in FIG. 4a according to still another embodiment of the present disclosure. In contrast to the display panel 10c illustrated in the FIG. 3a, the display panel 10c illustrated in FIG. 4a further includes a third dam 15 that is located at the non-display area B. The third dam 15 covers the first end portion 11b of the first signal transmission layer 11 and the second end portion 12b of the second signal transmission layer 12. The first dam 13 and the second dam 14b are located at the at a side of the third dam 15 close to the display area A. Along the first direction X, a second width is defined by a distance between the third dam 15 and the display area A of the display panel 10c. The second width is greater than the first width. A distance between the first dam 13 and the second dam 14b along the first direction X is substantially 30 μm-40 μm, for example, 30 μm, 40 μm, 45 μm, and so on. A distance between the third dam 15 and the second dam 14b along the first direction X may be adjusted based on an actual product design, which may be 30 μm-50 μm, for example, 30 μm, 40 μm, 45 μm, and so on. In this way, the width of each of the first signal transmission layer 11 and the second signal transmission layer 12 is increased to improve the display performance.

In some embodiments, the third dam 15 includes the first blocking layer (i.e., PLN2) 151 and a second blocking layer (i.e., PLN3) 152. The first blocking layer 151 is disposed on the base 1 and covers the first end portion 11b of the first signal transmission layer 11, which realizes a covering of the first end portion 11b (i.e., enclosing an edge of the first end portion 11b) and avoids the first signal transmission layer 11 from a corrosion or a short circuit due to being in contact with other conductive materials. The second end portion 12b of the second signal transmission layer 12 is disposed or stacked on a surface of a side of the first blocking layer 151 away from the base 1. The second blocking layer 152 is disposed on a surface of a side of the second end portion 12b away from the first blocking layer 151 and covers the second end portion 12b, which realizes a covering of the second end portion 12b (i.e., enclosing an edge of the second end portion 12b) and avoids the second signal transmission layer 12 from a corrosion or a short circuit due to being in contact with other conductive materials. In some embodiments, a material of each of the first blocking layer 151 and the second blocking layer 152 may be substantially identical to a material of each of the third blocking layer 131 and the fourth blocking layer 141.

In some embodiments, an orthographical projection of the first blocking layer 151 on the base 1 is located within an orthographical projection of the second blocking layer 152 on the base 1, thereby improving a covering effect of the third dam 15 to the first end portion 11b and the second end portion 12b.

In some embodiments, an orthographical projection of the second end portion 12b on the base 1 covers an orthographical projection of the first end portion 11b on the base 1, thereby further improving the covering effect of the third dam 15 to the first end portion 11b and the second end portion 12b.

In some embodiments, a third distance is defined by a distance between a surface of a side of the second blocking layer 152 away from the base 1 and the base 1. The third distance is substantially equal to the each of the first distance and the second distance. In this way, in addition to perform the covering of each of the first end portion 11b and the second end portion 12b, the third dam 15 is ensured to have a substantially same height as each of the third blocking layer 131 of first dam 13 and the fourth blocking layer 141 of the second dam 14b, thereby facilitating the manufacturing process.

An extension of at least one of the first signal transmission layer 11 and the second signal transmission layer 12 occupies a part of an area originally occupied by the encapsulation layer of the first display panel 10c, which hinders an encapsulation performance of each of the first end portion 11b and the second end portion 12b at a position that corresponds to the first end portion 11b and the second portion 12b. Therefore, in some embodiments, a part of a surface of a side of an encapsulation layer (i.e., CVD1+CVD2) that corresponds to the second blocking layer 152 away from the base 1 is substantially in a concave, convex, or curved shape, which extends a path of outside water vapor and etc. entering the second blocking layer 152 and improves an encapsulation reliability to the each of the first end portion 11b and the second end portion 12b.

In some embodiments, a width of each of the first blocking layer 151 and the second blocking layer 152 of the third dam 15 along the first direction X is less than a width of each of the first dam 13 and the second dam 14b along the first direction X, so as to save materials and narrow the bezel. In some embodiments, the width of each of the first blocking layer 151 and the second blocking layer 152 of the third dam 15 along the first direction X is less than or equal to 20 μm, for example, 10 μm, 15 μm, 18 μm, 20 μm, and so on.

In some embodiments, a side of a section of each of the third blocking layer 131 and the fourth blocking layer 141 along a direction substantially perpendicular to the base 1 is in shape of a smooth curve, e.g., a concave curve or a convex curve. In some embodiments, the side of the section of each of the third blocking layer 131 and the fourth blocking layer 141 along the direction substantially perpendicular to the base 1 includes a trapezoidal or trapezoidal-like shape.

In some embodiments, as illustrated in FIG. 4a, a side of a section of each of the first dam 13, the second dam 14b, and the third dam 15 along a direction substantially perpendicular to the base 1 is in shape of a smooth curve, e.g., a concave curve or a convex curve. In some embodiments, the side of the section of each of the first dam 13, the second dam 14b, and the third dam 15 along the direction substantially perpendicular to the base 1 includes a trapezoidal or trapezoidal-like shape. The second blocking layer 152, the third blocking layer 153, and the fourth blocking layer 154 are manufactured through the same process, which simplifies the manufacturing process and improves the efficiency.

In some embodiments, the third dam 15 may include only the second blocking layer 152. The second blocking layer 152 is disposed on the base 1 and covers the first end portion 11b of the first signal transmission layer 11 and the second end portion 12b of the second transmission layer 12, so as to realize a covering of each of the first end portion 11b and second end portion 12b and avoid the first signal transmission layer 11 and the second signal transmission layer 12 from a corrosion or a short circuit due to contact with other conductive materials.

In some embodiments, a material of each of the first blocking layer 151, the second blocking layer 152, the third blocking layer 131, and the fourth blocking layer 141 includes an organic.

It is to be noted that, a structure provided by each of the embodiments illustrated in FIGS. 1a-4a may be disposed on at least one of a left bezel or a right bezel. In some embodiments, the structure may be further disposed on a top bezel.

In the present embodiment, the display panel 10c has the display area A and the non-display area B, the display panel 10c includes the base 1, the first signal transmission layer 11, the second signal transmission layer 12, the first dam 13, and the second dam 14b. The first signal transmission layer 11 is disposed on the base 1. The second signal transmission layer 12 is disposed on a surface of a side of the first signal transmission layer 11 away from the base 1. The first dam 13 and the second dam 14b are located at the non-display area B and are spaced apart on a surface of a side of the second signal transmission layer 12 away from the base 1 along the extending direction of the second signal transmission layer 12. In some embodiments, the second dam 14b is located at a side of the first dam 13 away from the display area A. The first orthographic projection is defined by the orthographic projection of the second dam 14b on the base 1. The second orthographic projection is defined by the orthographic projection of the second end portion 12b of the second signal transmission layer 12 on the base 1. The first orthographic projection is located at a side of the second orthographic projection close to the display area A. In some embodiments, the first signal transmission layer 11 and the second signal transmission layer 12 are extended, the second signal transmission layer 12 is disposed or stacked on the first signal transmission layer 11, and the first dam 13 and the second dam 14b are disposed on a surface of a side of the second transmission layer 12 away from the base 1. That is to say, at positions where the first dam 13 and the second dam 14b are located, no other structural layer, e.g., the first organic layer 14m, is disposed between the first signal transmission layer 11 and the second signal transmission layer 12. In other words, the first organic layer 14m below the second dam 14a is removed from the display panel 10c. In this way, in addition to narrowing the bezel and realizing the high-brightness display, the display panel 10c further ensures that no height difference exists between a part of the second signal transmission layer 12 that corresponds to each of the first dam 13 and the second dam 14b and the remaining part of the second signal transmission layer 12, thereby further avoiding the over-etching phenomenon occurring at a part of the second signal transmission layer 12 that corresponds to the first dam 13 and the second dam 14b due to a non-uniform thickness of the photoresist resulted from a leveling process of the photoresist during a coating process. Therefore, the display panel 10c avoids the over-etching phenomenon that results in a part of the second signal transmission layer 12 that corresponds to the second dam 14b to be completely fractured. The fracture may increase the resistance of the second signal transmission layer 12. In this way, in case of the high-brightness display, the corresponding current may be increased greatly, thereby leading to an excessively high temperature of the display panel 10c. In some embodiments, the over-etching phenomenon may further result in an abnormal shape and a less reliable encapsulation of the second signal transmission layer 12, thereby leading to a problem, such as a black spot and a bright line, of the display panel under a high-temperature and high-humidity environment and further leading to a failure in the electronic device. Moreover, through removing the first organic layer 14m below the second dam 14b, the display panel 10c further enables the second signal transmission layer 12 to directly lap the first signal transmission layer 11 at a position where the second dam 14b is located, which increases an effective lap area between the first signal transmission layer 11 and the second signal transmission layer 12 and reduces the resistance.

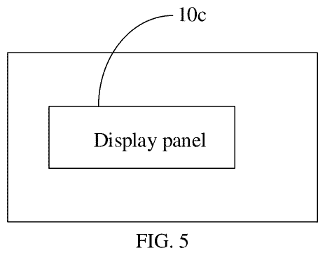

As illustrated in FIG. 5, FIG. 5 is a schematic structural view of an electronic device according to an embodiment of the present disclosure. An electronic device is provided by some embodiments of the present disclosure. The electronic device includes the display panel 10c mentioned in the above embodiments. A specific structure and function of the display panel 10c may refer to the above description, which will not be repeated herein. The electronic device may be a cell phone, a tablet, a laptop, a television, and any other product or component that has a display function. The electronic device may further include a main board, a control circuit, and so on. A structure of each of the main board, the control circuit, and etc., may be identical or similar to a relevant structure of an existing display device, which will not be repeated herein.

The above is merely some implementations of the present disclosure and thus may not limit the scope of the present disclosure. Any equivalent structure or any equivalent process transformation, either directly or indirectly, applied in a relevant technical field falls within the scope of the present disclosure.

What is claimed is:

1. A display panel with a display area and a non-display area, comprising:
a base;
a first signal transmission layer and a second signal transmission layer, the first signal transmission layer being disposed on the base, and the second signal transmission layer being disposed on a surface of a side of the first signal transmission layer away from the base; and
a first dam and a second dam, being located at the non-display area and spaced apart from one another along an extending direction of the second signal transmission layer on a surface of a side of the second signal transmission layer away from the base;
wherein the second dam is located at a side of the first dam away from the display area, a first orthographic projection is defined by an orthographic projection of the second dam on the base, a second orthographic projection is defined by an orthographic projection of a second end portion of the second signal transmission layer on the base, and the first orthographic projection is located at a side of the second orthographic projection close to the display area.

2. The display panel as claimed in claim 1, wherein a third orthographic projection is defined by an orthographic projection of a first end portion of the first signal transmission layer on the base and the first orthographic projection is located at a side of the third orthographic projection close to the display area.

3. The display panel as claimed in claim 2, wherein
the first signal transmission layer comprises a first body portion and the first end portion, and the first end portion is connected to a side of the first body portion away from the display area along a direction of the non-display area away from the display area; and
the second signal transmission layer comprises a second body portion and the second end portion, and the second end portion is connected to a side of the second body portion away from the display area along the direction of the non-display area away from the display area;
wherein the second body portion is disposed on a surface of a side of the first body portion away from the base.

4. The display panel as claimed in claim 3, wherein an orthographical projection of each of the first dam and the second dam on the base is located within an orthographical projection of each of the first body portion and the second body portion on the base.

5. The display panel as claimed in claim 2, further comprising:
a third dam, located at the non-display area and covering each of the first end portion and the second end portion, wherein the second dam is disposed at a side of the third dam close to the display area.

6. The display panel as claimed in claim 5, wherein the third dam comprises:
a first blocking layer, disposed on the base and covering the first end portion, wherein the second end portion is disposed on a surface of a side of the first blocking layer away from the base; and
a second blocking layer, disposed on a surface of a side of the second end portion away from the first blocking layer and covering the second end portion.

7. The display panel as claimed in claim 6, wherein an orthographical projection of the first blocking layer on the base is located within an orthographical projection of the second blocking layer on the base.

8. The display panel as claimed in claim 7, wherein
an orthographical projection of the second end portion on the base overlays an orthographical projection of the first end portion on the base.

9. The display panel as claimed in claim 6, wherein the first dam comprises a third blocking layer and the second dam comprises a fourth blocking layer;
the third blocking layer and the fourth blocking layer are disposed on the surface of the side of the second signal transmission layer away from the base.

10. The display panel as claimed in claim 9, wherein
along a layering direction of the display panel, a first distance is defined by a distance between the base and a surface of a side of the third blocking layer away from the base, a second distance is defined by a distance between the base and a surface of a side of the fourth blocking layer away from the base, and the first distance is substantially equal to the second distance.

11. The display panel as claimed in claim 9, wherein along the layering direction of the display panel, a thickness of the third blocking layer is substantially equal to a thickness of the fourth blocking layer.

12. The display panel as claimed in claim 11, wherein
a third distance is defined by a distance between a surface of a side of the second blocking layer away from the base and the base, and the third distance is substantially equal to each of the first distance and the second distance.

13. The display panel as claimed in claim 9, wherein a shape of a section of each of the third blocking layer and the fourth blocking layer along a direction substantially perpendicular to the base comprises a trapezoidal shape.

14. The display panel as claimed in claim 13, wherein a shape of a section of each of the first dam, the second dam, and the third dam along the direction substantially perpendicular to the base comprises a trapezoidal shape.

15. The display panel as claimed in claim 13, wherein
the third blocking layer and the fourth blocking layer are disposed on a same layer.

16. The display panel as claimed in claim 13, wherein
a material of each of the first blocking layer, the second blocking layer, the third blocking layer, and the fourth blocking layer comprises an organic.

17. The display panel as claimed in claim 1, wherein a part of each of the first signal transmission layer and the second signal transmission layer that corresponds to each of the first dam and the second dam is a continuous film layer.

18. The display panel as claimed in claim 6, wherein
the width of each of the first blocking layer and the second blocking layer of the third dam along a first direction is less than or equal to 20 μm.

19. The display panel as claimed in claim 3, wherein
a distance between the orthographic projection of the first end portion and the orthographic projection of the second dam on the base along a first direction is defined as a first size, the first size is 30 μm-50 μm, a distance between the orthographic projection of the second end portion and the orthographic projection of the second dam on the base along the first direction is defined as a second size, and the second size is 30 μm-50 μm.

20. An electronic device, comprising a display panel having a display area and a non-display area, wherein the display panel further comprises:
a base;
a first signal transmission layer and a second signal transmission layer, the first signal transmission layer being disposed on the base, and the second signal transmission layer being disposed on a surface of a side of the first signal transmission layer away from the base; and
a first dam and a second dam, being located at the non-display area and spaced apart from one another along an extending direction of the second signal transmission layer on a surface of a side of the second signal transmission layer away from the base;
wherein the second dam is located at a side of the first dam away from the display area, a first orthographic projection is defined by an orthographic projection of the second dam on the base, a second orthographic projection is defined by an orthographic projection of a second end portion of the second signal transmission layer on the base, and the first orthographic projection is located at a side of the second orthographic projection close to the display area.
